(19) United States
(12) Patent Application Publication
(10) Pub. No.: US 2014/0028399 A1
(43) Pub. Date: Jan. 30, 2014

(54) Signal Amplifier

(71) Applicant: NOVATEK Microelectronics Corp., Hsin-Chu (TW)

(72) Inventors: Chia-Hung Lin, Hsinchu City (TW); Jr-Ching Lin, Hsinchu City (TW)

(73) Assignee: NOVATEK Microelectronics Corp., Hsin-Chu (TW)

(21) Appl. No.: 13/949,179

(22) Filed: Jul. 23, 2013

(30) Foreign Application Priority Data
Jul. 24, 2012 (TW) 101126589

(51) Int. Cl. H03F 3/16

(52) U.S. Cl. CPC H03F 3/16
USPC 330/278

(57) ABSTRACT

A signal amplifier is disclosed. The signal amplifier includes a first transistor, including a first terminal, a second terminal and a control terminal; a resistor, including one terminal coupled to the first terminal of the first transistor, and another terminal coupled to the control terminal of the first transistor; and a capacitor, including one terminal coupled to the control terminal of the first transistor, and another terminal coupled to a specific voltage.

### BACKGROUND OF THE INVENTION

1. Field of the Invention

The present invention relates to a signal amplifier, and more particularly, to a signal amplifier capable of generating a zero for compensating signal attenuation to increase high frequency gain.

2. Description of the Prior Art

In general, the signal amplifier has the phenomenon of signal attenuation due to the effect of low pass channel and the parasitic capacitance inside the amplifier. In order to compensate signal attenuation, the common method is to add a zero in the signal path to increase the signal gain for compensation. In the prior art, the common method of inserting a zero is using capacitive degeneration or inductive load, etc.

For example, please refer to FIG. 1A and FIG. 1B. FIG. 1A is a schematic diagram of a conventional differential signal amplifier 10 and FIG. 1B is a schematic diagram of small signal equivalent circuit of a part of the differential signal amplifier 10 in FIG. 1A. As shown in FIG. 1A and FIG. 1B, a resistor Rs and a capacitor Cs are added between the sources of transistors M₁ and M₂ in the conventional differential signal amplifier 10 to form the structure of source capacitive degradation to generate a zero Z₁=1/RsCs.

On the other hand, please refer to FIG. 2, which is a schematic diagram of a conventional single-ended signal amplifier 20. As shown in FIG. 2, a load resistor Rd is coupled to an inductor in series in the conventional single-ended signal amplifier 20 and forms inductive load to generate a zero Z₂=Rd/Ld.

The above structures of the signal amplifier 10 and the single-ended signal amplifier 20, and the method of generating zeros are known by those skilled in the art. However, utilizing only capacitive degeneration or inductive load to add zeros is lack of flexibility in application. Thus, there is a need to provide other method of adding zeros.

### SUMMARY OF THE INVENTION

A signal amplifier is provided, capable of generating a zero for compensating signal attenuation to increase high frequency gain.

A signal amplifier is disclosed. The signal amplifier comprises a first transistor, comprising a first terminal, a second terminal and a control terminal, a resistor, comprising one terminal coupled to the first terminal of the first transistor, and another terminal coupled to the control terminal of the first transistor, and a capacitor, comprising one terminal coupled to the control terminal of the first transistor, and another terminal coupled to a specific voltage.

A signal amplifier is further disclosed. The signal amplifier comprises a first transistor, comprising a first terminal, a second terminal and a control terminal, a resistor, comprising one terminal coupled to the control terminal of the first transistor, and another terminal coupled to the specific voltage, and a capacitor, comprising one terminal coupled to the second terminal of the first transistor, and another terminal coupled to the control terminal of the first transistor.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1A is a schematic diagram of a conventional differential signal amplifier.

FIG. 1B is a schematic diagram of small signal equivalent circuit of a part of the differential signal amplifier in FIG. 1A.

FIG. 2 is a schematic diagram of a conventional single-ended signal amplifier.

FIG. 3A is a schematic diagram of a single-ended signal amplifier according to an embodiment of the present invention.

FIG. 3B is a schematic diagram of small signal equivalent circuit of lower half of the single-ended signal amplifier in FIG. 3A.

FIG. 4, FIG. 5, and FIG. 6 are the schematic diagrams of other single-ended signal amplifier according to an embodiment of the present invention.

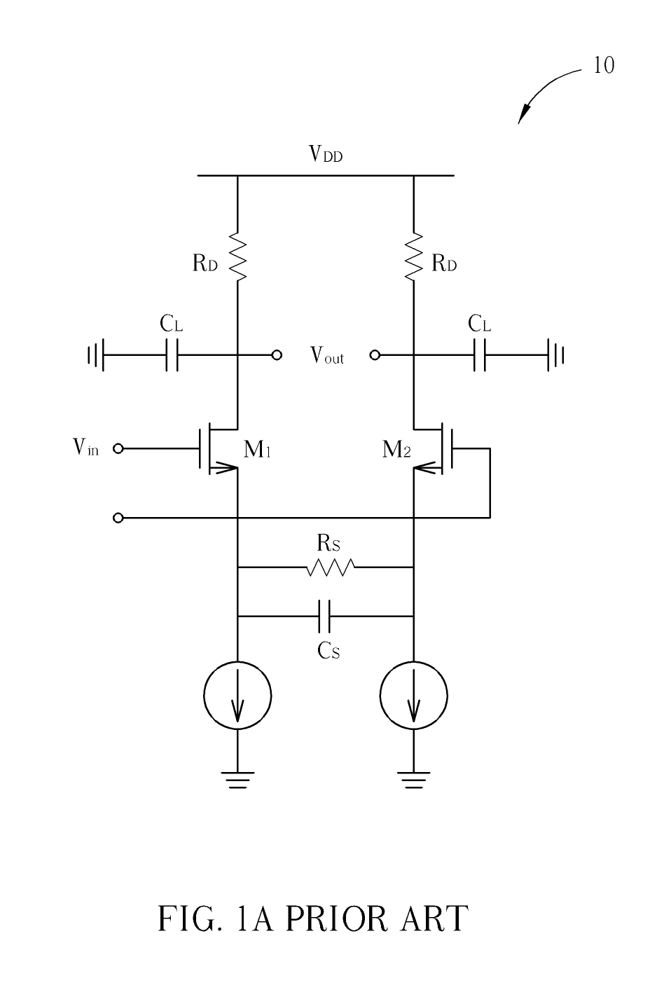

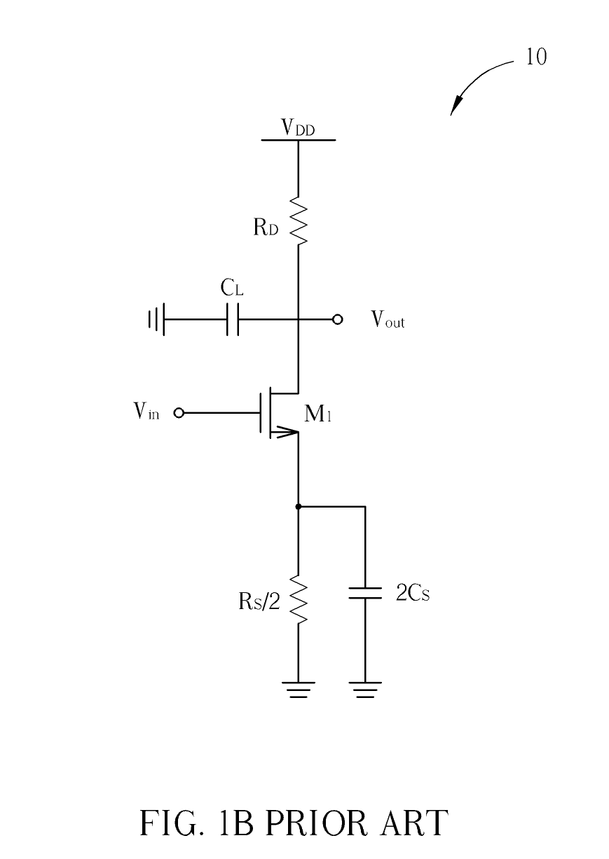

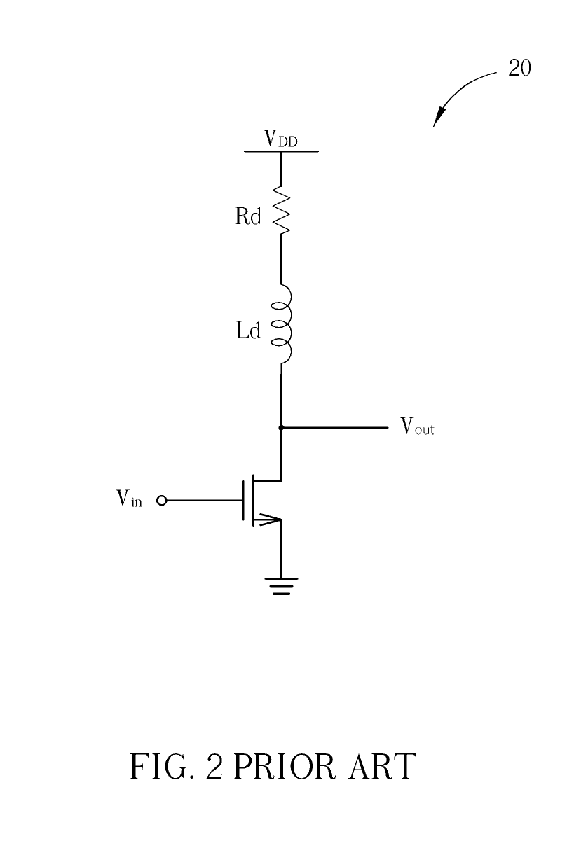

### DETAILED DESCRIPTION

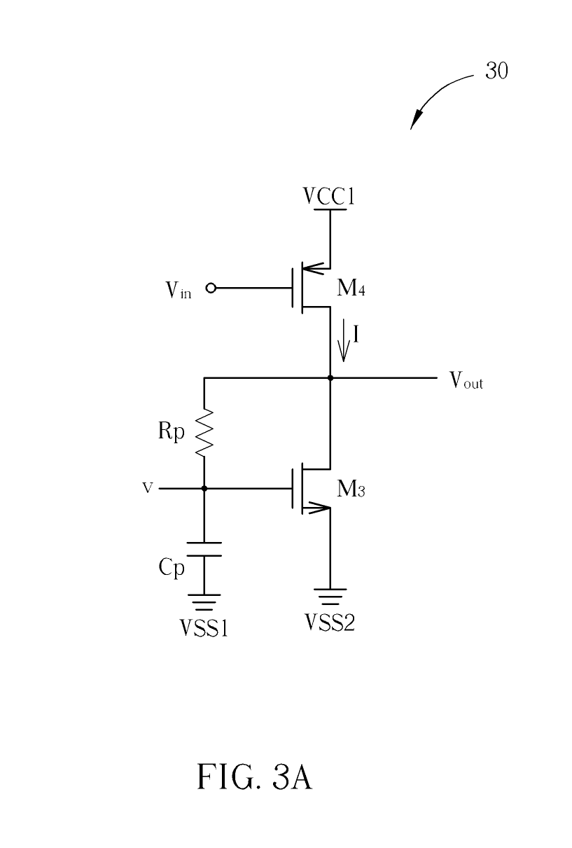

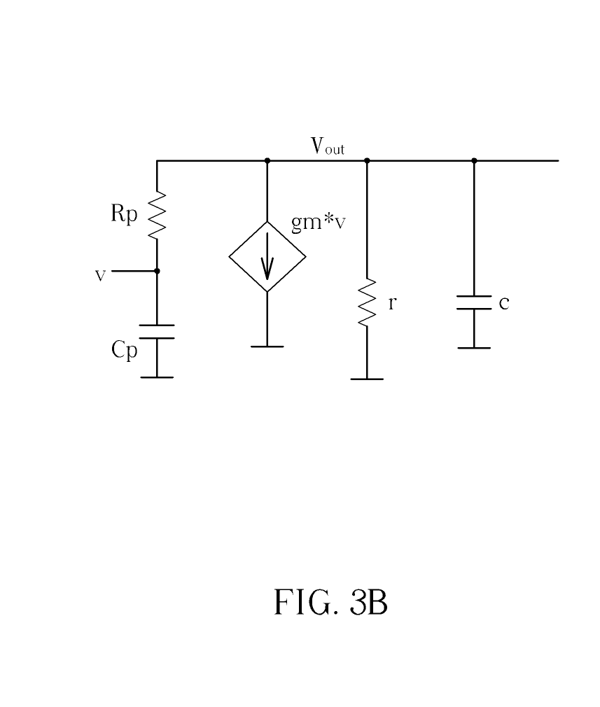

Please refer to FIG. 3A, which is a schematic diagram of a single-ended signal amplifier 30 according to an embodiment of the present invention. The single-ended signal amplifier 30 includes a transistor M₃, a transistor M₄, a resistor Rp, and a capacitor Cp. The detail structure and connection are as shown in FIG. 3. A terminal of the resistor Rp is coupled to a drain (i.e. a first terminal) of the transistor M₃ and another terminal of the resistor Rp is coupled to a gate (i.e. a control terminal) of the transistor M₃. A terminal of the capacitor Cp is coupled to the gate of the transistor M₃ and another terminal of the capacitor Cp is coupled to a ground voltage VSS1 (i.e. a specific voltage). A drain of the transistor M₄ is coupled to the drain of the transistor M₃ and outputs an output voltage Vout, a gate of the transistor M₄ is utilized for receiving an input voltage Vin, and a source (i.e. a second terminal) of the transistor M₄ is coupled to a system voltage VCC1. A source of the transistor M₃ is coupled to a ground voltage VSS2. The transistors M₃ and M₄ are an N-type metal oxide semiconductor (MOS) transistor and a P-type MOS transistor, respectively.

On the other hand, please refer to FIG. 3B, which is a schematic diagram of a small signal equivalent circuit of a lower half of the signal amplifier 30 in FIG. 3A, wherein a resistor r is the output equivalent resistance of the transistor M₃ and a capacitor c is the parasitic capacitance of the drain of the transistor M₃. As shown in FIG. 3A and FIG. 3B, a current I flowing from the drain of the transistor M₄ to the drain of the transistor M₃ is:

I=(Vout−v)/Rp+gm*v+Vout/r+s*c*Vout

Substituting the impedance as Vout/I and substituting a voltage v as the division voltage of voltage Vout into the above equation can get:

$$V out / I = \frac{( sRpCp + 1 ) r}{{s}^{2} crRpCp + ( Cpr + RpCp + cr ) s + gmr + 1}$$

From the above equation, the single-ended signal amplifier 30 gets a zero Z₃=1/RpCp. As a result, based on the original basic structure of the single-ended signal amplifier with the transistors M₃, M₄ connected in series, the present invention adds the resistor Rp between the drain and the source of the transistor M₃ and adds the capacitor Cp between the gate of the transistor M₃ and a ground voltage VSS1 to generate the zero Z₃=1/RpCp for compensating signal attenuation and increasing high frequency gain.

Noticeably, the main spirit of the present invention is adding the resistor Rp between the drain and the source of the transistor M₃ and adding the capacitor Cp between the gate of the transistor M₃ and a ground voltage VSS1 to generate the zero Z₃=1/RpCp for compensating signal attenuation and increasing high frequency gain. Those skilled in the art can make modifications or alterations accordingly. For example, the ground voltage or the system voltage for the specific voltage can be provided by a voltage source or a current source. Besides, the resistor Rp can be implemented by parasitic resistance, poly-silicon, metal, MOS or any type of resistance, and the capacitor Cp also can be implemented by the parasitic capacitance, poly-silicon, metal, MOS or any type of capacitance. Moreover, in the above single-ended signal amplifier 30, the transistor M₃ and M₄ are the N-type MOS transistor and P-type MOS transistor, respectively, the resistor Rp is coupled between the drain and the gate of the transistor M₃, and the capacitor Cp is coupled between the gate of the transistor M₃ and the ground voltage VSS1. In other embodiment, the transistors can be implemented by other type of arrangement, and the capacitor and the resistor can also be coupled in other manner.

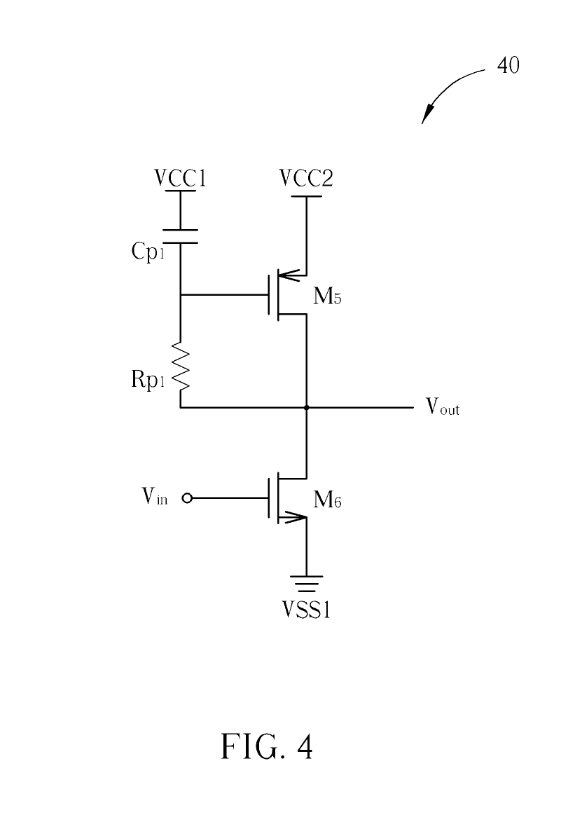

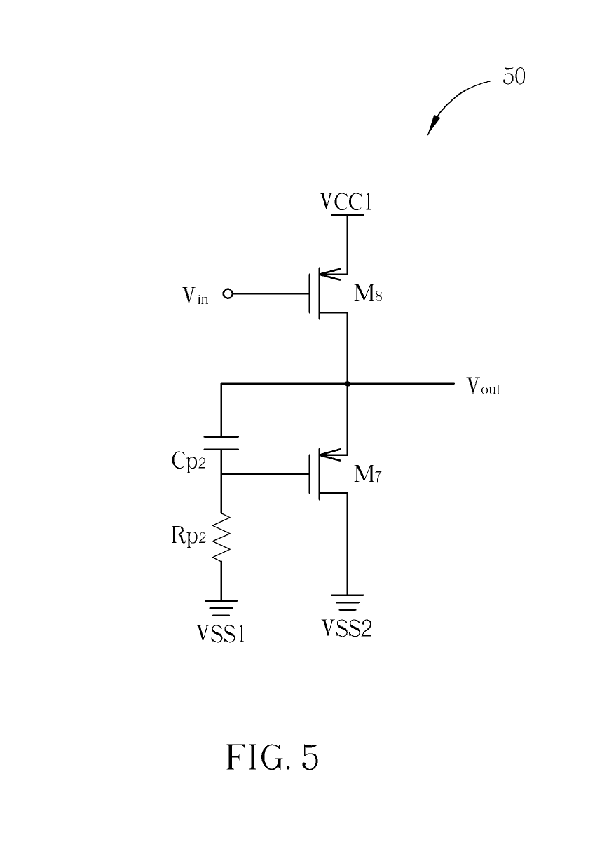

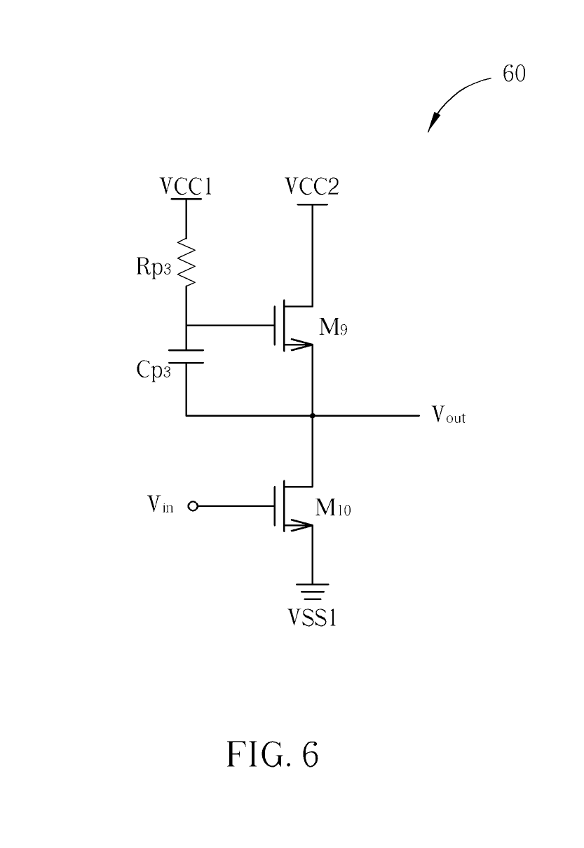

In detail, please refer to FIG. 4, FIG. 5, and FIG. 6, which are schematic diagrams of single-ended signal amplifiers 40, 50, and 60 according to embodiments of the present invention. As shown in FIG. 4, the single-ended signal amplifier 40 includes a transistor M₅, a transistor M₆, a resistor Rp₁, and a capacitor Cp₁. The detail structure and connection are shown in FIG. 4. A terminal of the resistor Rp₁ is coupled to a drain (i.e. a first terminal) of the transistor M₅ and another terminal of the resistor Rp₁ is coupled to a gate (i.e. a control terminal) of the transistor M₅. A terminal of the capacitor Cp₁ is coupled to the gate of the transistor M₅ and another terminal of the capacitor Cp₁ is coupled to a system voltage VCC1 (i.e. a specific voltage). A drain of the transistor M₆ is coupled to the drain of the transistor M₅ and outputs an output voltage Vout, a gate of the transistor M₆ is utilized for receiving an input voltage Vin, and a source (i.e. a second terminal) of the transistor M₆ is coupled to a ground voltage VSS1. A source of the transistor M₅ is coupled to a system voltage VCC2. The transistors M₅ and M₆ are a P-type MOS transistor and an N-type MOS transistor, respectively. In other words, the single-ended signal amplifier 40 and the single-ended signal amplifier 30 are partially similar, and the main differences are that the transistors M₅ and M₆ are P-type MOS transistor and N-type MOS transistor, respectively, and the capacitor Cp1 is coupled between the gate of the transistor M₅ and the system voltage VCC1 in the single-ended signal amplifier 40. In such a situation, by method similar to the above method for the single-ended signal amplifier 30, it can derive that the single-ended signal amplifier 40 has a zero Z₄=1/Rp₁Cp₁. As a result, the embodiment can also generate the zero Z₄=1/Rp₁Cp₁ for compensating signal attenuation and increasing high frequency gain.

As shown in FIG. 5, the single-ended signal amplifier 50 includes a transistor M₇, a transistor M₈, a resistor Rp₂, and a capacitor Cp₂. The detail structure and connection are shown in FIG. 5. A terminal of the resistor Rp₂ is coupled to a gate of the transistor M₇ and another terminal of the resistor Rp₂ is coupled to a ground voltage VSS1 (i.e. a specific voltage). A terminal of the capacitor Cp₂ is coupled to the source (i.e. a second terminal) of the transistor M₇ and another terminal of the capacitor Cp₂ is coupled to the gate (i.e. a control terminal) of the transistor M₇. A drain of the transistor M₈ is coupled to the source of the transistor M₇ and outputs an output voltage Vout, a gate of the transistor M₈ is utilized for receiving an input voltage Vin, and a source of the transistor M₈ is coupled to a system voltage VCC1. A drain of the transistor M₇ is coupled to a ground voltage VSS2. Both the transistors M₇ and M₈ are P-type MOS transistors. In other words, the single-ended signal amplifier 50 and the single-ended signal amplifier 30 are partially similar and the main differences are that both the transistors M₇ and M₈ are P-type MOS transistors, the resistor Rp₂ is coupled between the gate of the transistor M₇ and the ground voltage VSS1, and the capacitor Cp₂ is coupled between the source and the gate of the transistor M₇ in the single-ended signal amplifier 50. In such a situation, by method similar to the above method for the single-ended signal amplifier 30, it can also derive that the single-ended signal amplifier 50 has a zero Z₅=1/Rp₂Cp₂. As a result, the embodiment can also generate the zero Z₅=1/Rp₂Cp₂ for compensating signal attenuation and increasing high frequency gain.

As shown in FIG. 6, the single-ended signal amplifier 60 includes a transistor M₉, a transistor M₁₀, a resistor Rp₃, and a capacitor Cp₃. The detail structure and connection are shown in FIG. 6. A terminal of the resistor Rp₃ is coupled to a gate of the transistor M₉ and another terminal of the resistor Rp₃ is coupled to a system voltage VCC1 (i.e. a specific voltage). A terminal of the capacitor Cp₃ is coupled to the source (i.e. a second terminal) of the transistor M₉ and another terminal of the capacitor Cp₃ is coupled to the gate (i.e. a control terminal) of the transistor M₉. A drain of the transistor M₁₀ is coupled to the source of the transistor M₉ and outputs an output voltage Vout, a gate of the transistor M₁₀ is utilized for receiving an input voltage Vin, and a source of the transistor M₁₀ is coupled to a ground voltage VSS1. A drain of the transistor M₉ is coupled to a system voltage VCC2. Both the transistors M₉ and M₁₀ are N-type MOS transistors. In other words, the single-ended signal amplifier 60 and the single-ended signal amplifier 50 are partially similar and the main differences are that both the transistors M₉ and M₁₀ are N-type MOS transistors and the resistor Rp₃ is coupled between the gate of the transistor M₉ and the ground voltage VSS1 in the single-ended signal amplifier 60. In such a situation, by a method similar to the above method for the single-ended signal amplifier 30, it can also be derived that the single-ended signal amplifier 60 has a zero Z₆=1/Rp₃Cp₃. As a result, the embodiment can also generate the zero Z₆=1/Rp₃Cp₃ for compensating signal attenuation and increasing high frequency gain.

Besides, the resistors and the capacitors are added in the above single-ended signal amplifiers to generate zeros in above embodiments, but resistors and capacitors can also be added in similar locations in differential signal amplifiers to generate zeros in other embodiments. Additionally, the transistors are implemented by MOS transistors in the above embodiment, but the transistors can also be implemented by any type of transistor in other embodiment. As the transistors are implemented by bipolar junction transistors (BJTs), the first terminal, the second terminal, and the control terminal can be a collector, an emitter, and a base. All of these are known by those skilled in the art, and will not be narrated hereinafter.

In the prior art, only utilizing capacitive degeneration or inductive load to add zeros is lack of flexibility in application. In comparison, the embodiments can add the resistor and the capacitor between the drain and the gate of transistor and between and the gate of the transistor and a specific voltage to generate a zero for compensating signal attenuation and increasing high frequency gain.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A signal amplifier, comprising:
a first transistor, comprising a first terminal, a second terminal and a control terminal;
a resistor, comprising one terminal coupled to the first terminal of the first transistor, and another terminal coupled to the control terminal of the first transistor; and
a capacitor, comprising one terminal coupled to the control terminal of the first transistor, and another terminal coupled to a specific voltage.

2. The signal amplifier of claim 1, wherein the first transistor is a metal oxide semiconductor transistor and the first terminal, the second terminal, and the control terminal are a drain, a source, and a gate.

3. The signal amplifier of claim 1, further comprising:
a second transistor, comprising a first terminal, a second terminal and a control terminal, wherein the first terminal is coupled to the first terminal of the first transistor and the control terminal is utilized for receiving an input voltage.

4. The signal amplifier of claim 3, wherein the first transistor is an N-type metal oxide semiconductor transistor, the second transistor is a P-type metal oxide semiconductor transistor, and the specific voltage is a ground voltage.

5. The signal amplifier of claim 3, wherein the first transistor is a P-type metal oxide semiconductor transistor, the second transistor is an N-type metal oxide semiconductor transistor, and the specific voltage is a system voltage.

6. The signal amplifier of claim 1, wherein the specific voltage is provided by a voltage source or a current source.

7. The signal amplifier of claim 1, wherein the capacitor is a parasitic capacitor of the first transistor.

8. The signal amplifier of claim 1, wherein the first transistor is a bipolar junction transistor and the first terminal, the second terminal, and the control terminal are a collector, an emitter, and a base.

9. A signal amplifier, comprising:
a first transistor, comprising a first terminal, a second terminal and a control terminal;
a resistor, comprising one terminal coupled to the control terminal of the first transistor, and another terminal coupled to a specific voltage; and
a capacitor, comprising one terminal coupled to the second terminal of the first transistor, and another terminal coupled to the control terminal of the first transistor.

10. The signal amplifier of claim 9, wherein the first transistor is a metal oxide semiconductor transistor and the first terminal, the second terminal, and the control terminal are a drain, a source, and a gate.

11. The signal amplifier of claim 9, further comprising:
a second transistor, comprising a first terminal, a second terminal, and a control terminal, wherein the first terminal is coupled to the second terminal of the first transistor and the control terminal is utilized for receiving an input voltage.

12. The signal amplifier of claim 11, wherein the first transistor is a P-type metal oxide semiconductor transistor, the second transistor is a P-type metal oxide semiconductor transistor, and the specific voltage is a ground voltage.

13. The signal amplifier of claim 11, wherein the first transistor is an N-type metal oxide semiconductor transistor, the second transistor is an N-type metal oxide semiconductor transistor, and the specific voltage is a system voltage.

14. The signal amplifier of claim 9, wherein the specific voltage is provided by a voltage source or a current source.

15. The signal amplifier of claim 9, wherein the capacitor is a parasitic capacitor of the first transistor.

16. The signal amplifier of claim 9, wherein the first transistor is a bipolar junction transistor and the first terminal, the second terminal, and the control terminal are a collector, an emitter, and a base.
